(19) United States
(12) Patent Application Publication
(10) Pub. No.: US 2026/0293139 A1
(43) Pub. Date: Sep. 24, 2026

(54) MEMORY DEVICE AND MANUFACTURING METHOD THEREFOR

(71) Applicant: PEKING UNIVERSITY, Beijing (CN)

(72) Inventors: Zongwei WANG, Beijing (CN); Yimao CAI, Beijing (CN); Tianyang LUO, Beijing (CN); Haisu ZHANG, Beijing (CN)

(73) Assignee: PEKING UNIVERSITY, Beijing (CN)

(21) Appl. No.: 19/572,319

(22) Filed: Mar. 19, 2026

(30) Foreign Application Priority Data
Mar. 20, 2025 (CN) 202510332312.0

(51) Int. Cl. H10B 43/35; H10B 43/10; H10B 43/27

(52) U.S. Cl. CPC H10B 43/35; H10B 43/10; H10B 43/27

(57) ABSTRACT

Disclosed are a memory device and a manufacturing method therefor. The memory device includes: a substrate, a source line disposed on the substrate and connected to the substrate, a plurality of select lines disposed on a side of the source line away from the substrate and arranged at intervals along a first direction perpendicular to the substrate, a channel structure extending through the plurality of select lines along the first direction, with a bottom of the channel structure being connected to the source line, and a bit line disposed on a side of the channel structure away from the source line.

### CROSS-REFERENCE TO RELATED APPLICATIONS

This application claims priority to Chinese patent application No. 202510332312.0, filed on Mar. 20, 2025, entitled "MEMORY DEVICE AND MANUFACTURING METHOD THEREFOR", and the content of which is hereby incorporated by reference in its entirety.

### TECHNICAL FIELD

The present disclosure relates to the field of integrated circuits, and in particular, to a memory device and a manufacturing method thereof.

### BACKGROUND

Not AND Flash (NAND) is a type of non-volatile memory. The NAND Flash memory has the advantages of high storage density, low cost, long service life, and low power consumption, and is widely applied in the fields of solid state drives, USB flash disks, memory cards, embedded systems, and the like.

At present, the NAND Flash memory improves the storage density by means of vertical stacking, and realizes series connection of memory cells in a vertical manner, thereby achieving a higher storage density and a lower cost. However, the NAND Flash memory still has many problems.

### SUMMARY

In a first aspect, a memory device is provided. The memory device includes a substrate, a source line, a plurality of select lines, a channel structure, and a bit line. The source line is disposed on the substrate and connected to the substrate. The plurality of select lines is disposed on a side of the source line away from the substrate. The plurality of select lines is arranged at intervals along a first direction perpendicular to the substrate. The channel structure extends through the plurality of select lines along the first direction. A bottom of the channel structure is connected to the source line. Along a direction from the select line toward a central direction of the channel structure, the channel structure includes a gate dielectric layer, a charge trapping layer, a tunneling layer, a channel layer, and a core pillar arranged in sequence. The core pillar includes a first isolation layer, a conductive layer, and a second isolation layer arranged in sequence along a direction away from the source line. The bit line is disposed on a side of the channel structure away from the source line.

In an embodiment, the plurality of select lines includes a source select line, a plurality of word lines, and a drain select line arranged in sequence along the first direction.

In an embodiment, a top surface of the first isolation layer is lower than the plurality of word lines, a bottom surface of the second isolation layer is higher than the plurality of word lines, and the conductive layer is disposed between the top surface of the first isolation layer and the bottom surface of the second isolation layer.

In an embodiment, the source line is connected to the channel structure in a one-to-one correspondence, or an adjacent plurality of the channel structures are connected to the same source line.

In a second aspect, a memory device is provided. The memory device includes a substrate, a source line, a memory string, a plurality of word lines, a source select line, a drain select line, and a bit line. The source line is disposed on the substrate and connected to the substrate. The memory string is disposed on a side of the source line away from the substrate, and the memory string is connected to the substrate through the source line. The memory string includes a lower select transistor, a plurality of memory cells, and an upper select transistor arranged in sequence along a first direction perpendicular to the substrate. Each memory cell includes a memory transistor and a bypass resistor connected in parallel with the memory transistor. The plurality of word lines is arranged at intervals along the first direction, and each word line is connected to a control gate of the memory transistor arranged on the same layer. The source select line is disposed below the plurality of word lines, and the source select line is connected to a control gate of the lower select transistor. The drain select line is disposed above the plurality of word lines, and the drain select line is connected to a control gate of the upper select transistor. The bit line is disposed on a side of the upper select transistor away from the substrate, and the bit line is connected to the upper select transistor of at least one memory string.

In an embodiment, the source line is connected to the memory string in a one-to-one correspondence, or an adjacent plurality of the memory strings are connected to the same source line.

In an embodiment, the memory strings are arranged in a plurality of columns along a second direction parallel to the substrate, the plurality of columns of memory strings are arranged at intervals along a third direction, and the third direction is parallel to the substrate and intersects with the second direction. The bit line extends over the memory strings along the second direction, and each bit line is connected to each column of the memory strings.

In a third aspect, a manufacturing method for a memory device is provided. The method includes: providing a substrate, and forming a source line on a side of the substrate; forming a stacked structure on a side of the source line away from the substrate, where the stacked structure includes alternating insulating layers and sacrificial layers; forming a first hole, where the first hole penetrates the stacked structure along a first direction perpendicular to the substrate, and the first hole exposes a partial top surface of the source line; forming a channel structure in the first hole, where along a direction from the stacked structure toward a central direction of the channel structure, the channel structure includes a gate dielectric layer, a charge trapping layer, a tunneling layer, a channel layer, and a core pillar arranged in sequence, and the core pillar includes a first isolation layer, a conductive layer, and a second isolation layer arranged in sequence along a direction away from the source line; removing the sacrificial layers, and filling a conductive material in regions where the sacrificial layers are removed to form a plurality of select lines arranged at intervals along the first direction; and forming a bit line on a side of the channel structure away from the source line.

In an embodiment, forming the channel structure in the first hole includes: forming a gate dielectric layer, a charge trapping layer, a tunneling layer, and a channel layer that cover an inner sidewall of the first hole in sequence, where at least a part of a bottom surface of the channel layer is in contact with the source line; and forming a first isolation layer, a conductive layer, and a second isolation layer on an inner side of the channel layer, where the first isolation layer, the conductive layer, and the second isolation layer are arranged in sequence along a direction away from the substrate.

In an embodiment, each first hole is formed corresponding to each source line, and the source lines are connected to the channel structures in a one-to-one correspondence; or, a plurality of first holes are formed on each source line, and an adjacent plurality of the channel structures are connected to the same source line.

### BRIEF DESCRIPTION OF DRAWINGS

To describe the technical solutions in the embodiments of the present disclosure or in the conventional technology more clearly, the accompanying drawings that are needed in the description of the embodiments or the conventional technology will be briefly introduced below. It is obvious that the accompanying drawings described below are only some embodiments of the present disclosure, and other drawings can be obtained by those of ordinary skill in the art without creative work according to these accompanying drawings.

FIG. 1 is a schematic structural view of a memory device provided in an embodiment.

FIG. 2 is a schematic structural view of a memory device provided in another embodiment.

FIG. 3 is a top view of the memory device in FIG. 2.

FIG. 4 is a schematic circuit diagram of a memory device provided in an embodiment.

FIG. 5 is a circuit diagram of a memory device provided in an embodiment.

FIG. 6 is a process flow chart of a manufacturing method of a memory device provided in an embodiment.

FIG. 7 is a schematic view of a substrate integrated with a drive circuit layer provided in an embodiment.

FIG. 8 is a schematic view after forming a second dielectric layer provided in an embodiment.

FIG. 9 is a schematic view after forming a first via hole provided in an embodiment.

FIG. 10 is a schematic view after forming a connecting plug provided in an embodiment.

FIG. 11 is a schematic view after forming a source line provided in an embodiment.

FIG. 12 is a schematic view after forming a stacked structure provided in an embodiment.

FIG. 13 is a schematic view after forming a first hole provided in an embodiment.

FIG. 14 is a schematic view after forming a gate dielectric layer, a charge trapping layer, and a tunneling layer that cover an inner sidewall of a first hole in sequence, provided in an embodiment.

FIG. 15 is a schematic view after forming a protective layer provided in an embodiment.

FIG. 16 is a schematic view after removing the protective layer, the gate dielectric layer, the charge trapping layer, and the tunneling layer from the bottom surface of a first hole provided in an embodiment.

FIG. 17 is a schematic view after removing a protective layer provided in an embodiment.

FIG. 18 is a schematic view after forming a channel layer provided in an embodiment.

FIG. 19 is a schematic view after depositing a first isolation layer provided in an embodiment.

FIG. 20 is a schematic view after etching back a first isolation layer provided in an embodiment.

FIG. 21 is a schematic view after depositing a conductive layer provided in an embodiment.

FIG. 22 is a schematic view after etching back a conductive layer provided in an embodiment.

FIG. 23 is a schematic view after depositing a second isolation layer provided in an embodiment.

FIG. 24 is a schematic view after etching back a second isolation layer provided in an embodiment.

FIG. 25 is a schematic view after forming a bit line contact provided in an embodiment.

FIG. 26 is a schematic view after removing a sacrificial layer provided in an embodiment.

FIG. 27 is a schematic view after forming a high-k material layer and select lines provided in an embodiment.

### DETAILED DESCRIPTION

To facilitate understanding of the present disclosure, the present disclosure will be described more comprehensively below with reference to relevant drawings. Some embodiments of the present disclosure are shown in the drawings. However, the present disclosure may be implemented in many different forms and is not limited to the embodiments described herein. On the contrary, these embodiments are provided to disclose the present disclosure more comprehensively.

Unless otherwise defined, all technical and scientific terms used herein have the same meanings as commonly understood by those skilled in the art to which the present disclosure belongs. The terms used herein in the specification of the present disclosure are only for the purpose of describing specific embodiments, and are not intended to limit the present disclosure.

NAND Flash memory still has many deficiencies. The array structure of NAND Flash memory may cause problems such as response delay, power consumption, and bandwidth limit.

For example, a memory string of a NAND Flash memory is formed by connecting flash memory cells in series. A current path can be formed only when all flash memory cells on the memory string are turned on, and the memory string can only read the stored data of one flash memory cell at a time. When reading a certain flash memory cell, all flash memory cells on the same memory string need to be in a turned-on state; that is, a high voltage needs to be applied to the gates of the flash memory cells, resulting in a long charge-discharge time and high dynamic power consumption.

In addition, the memory strings of the NAND Flash memory cannot be led out independently. On the side close to the upper select transistor, thousands of memory strings in one plane are connected to the same bit line (BL). On the side close to the lower select transistor, tens of thousands of memory strings in one block are connected to the same source line (SL). This lead-out method means that each bit line (BL) can only read one memory string at a time, which limits the amount of stored information that can be read at a single time, and limits the sequential read bandwidth of the NAND Flash memory.

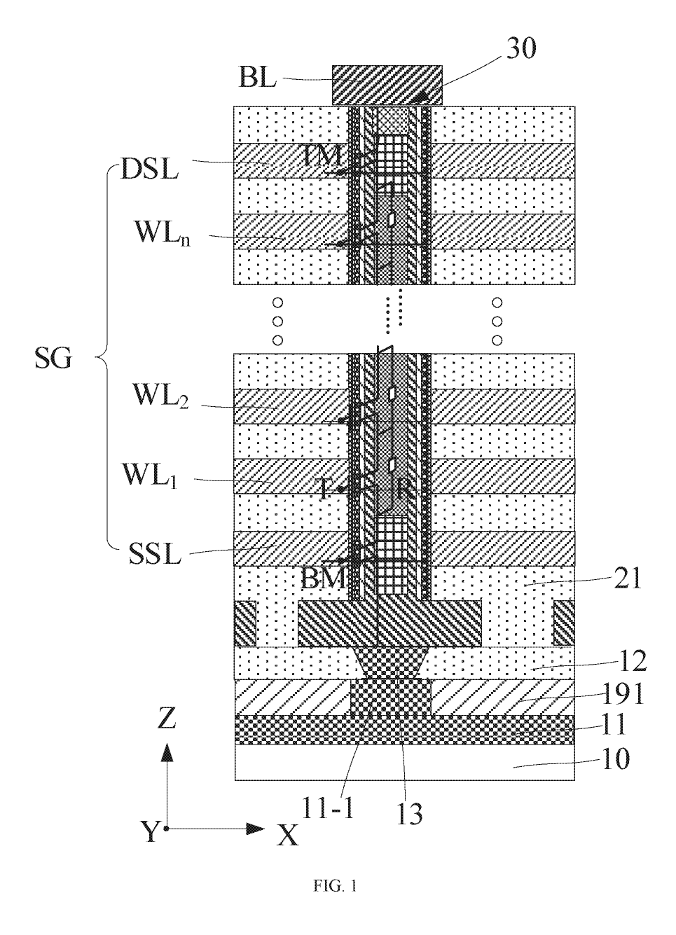

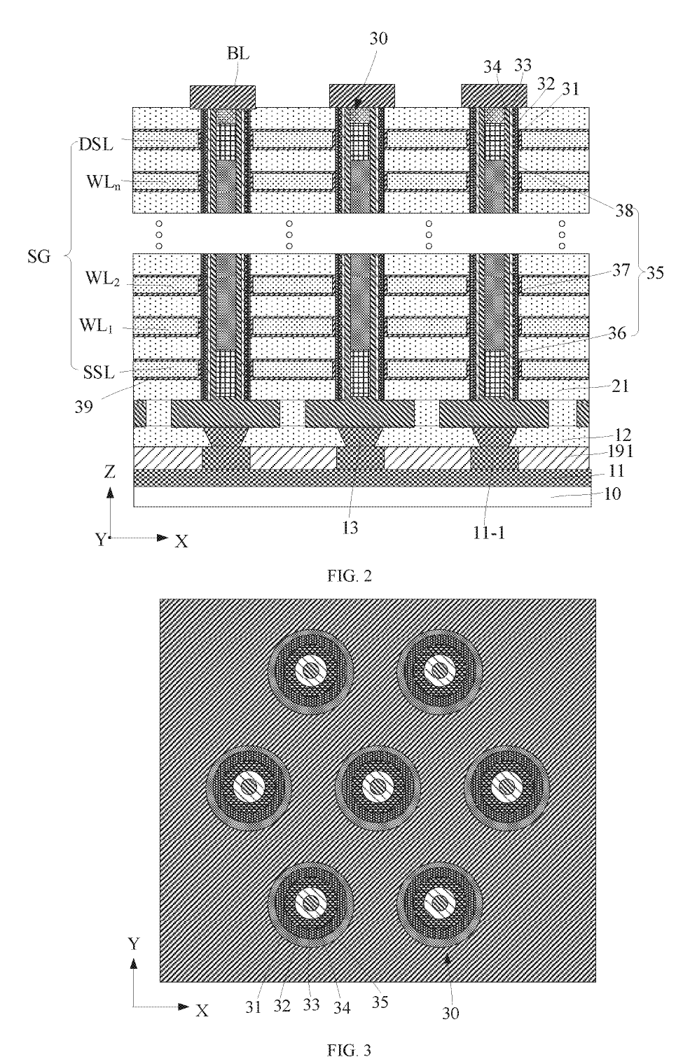

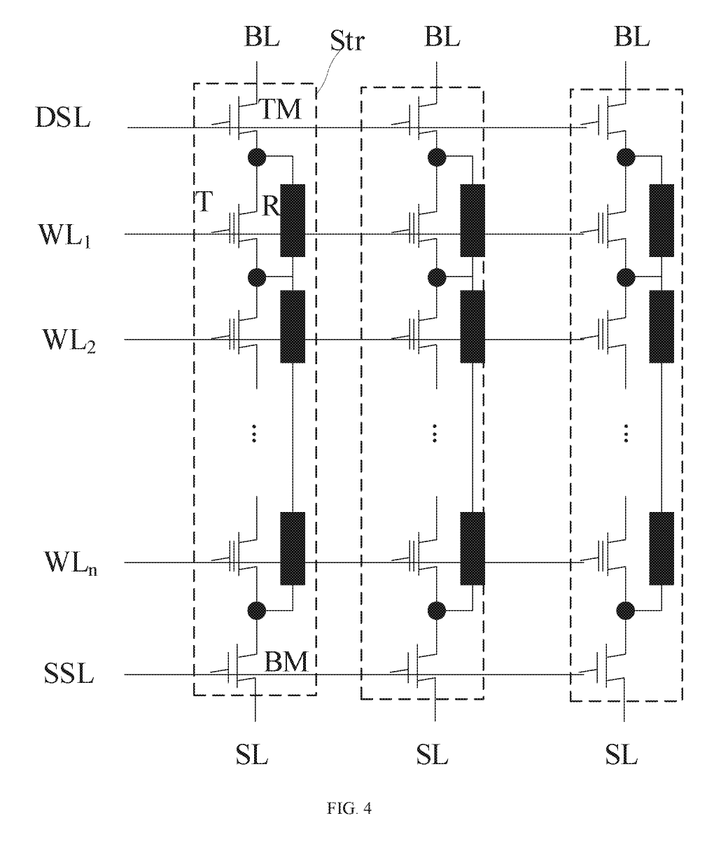

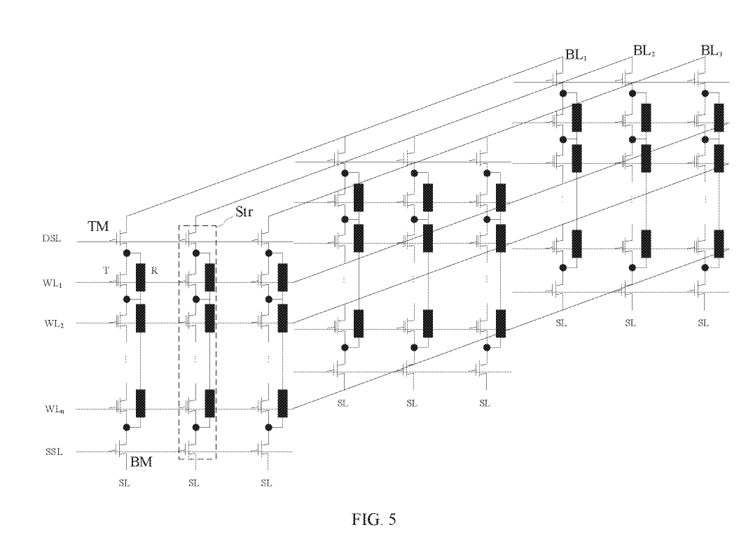

According to an embodiment, a memory device is provided by the present disclosure. As shown in FIG. 1 to FIG. 5, the memory device includes a substrate 10, a source line SL, a plurality of select lines SG, a channel structure 30, and a bit line BL. A driver circuit layer 11 may be integrated on the substrate 10. The driver circuit layer 11 is configured to provide a voltage signal or a current signal to the memory device to control a write or read operation of the memory device. The source line SL is disposed on the substrate 10 and connected to the substrate 10. The plurality of select lines SG are disposed on a side of the source line SL away from the substrate 10, and the plurality of select lines SG are arranged at intervals along a first direction Z perpendicular to the substrate 10. The channel structure 30 extends through the plurality of select lines SG along the first direction Z, and a bottom of the channel structure 30 is connected to the source line SL. Along a direction from the select lines SG towards a center of the channel structure 30, the channel structure 30 includes a gate dielectric layer 31, a charge trapping layer 32, a tunneling layer 33, a channel layer 34, and a core pillar 35, which are arranged in sequence. The core pillar 35 includes a first isolation layer 36, a conductive layer 37, and a second isolation layer 38, which are arranged in sequence along a direction away from the source line SL. The bit line BL is disposed on a side of the channel structure 30 away from the source line SL.

The conductive layer 37 is located between the first isolation layer 36 and the second isolation layer 38. The conductive layer 37 forms a bypass resistor R connected in series with the memory transistor T of the memory string Str, so that a current of the memory string Str can form a current path through the bypass resistor R without requiring all memory transistors T to be turned on. As such, the read operation of the memory cell T-R can be simplified. When reading the memory cell T-R, a high voltage only needs to be applied to the memory cell T-R to be read, and there is no need to apply a high voltage to the plurality of memory cells T-R of the entire memory string Str.

In the memory device of this embodiment, the core pillar 35 of the channel structure 30 includes the first isolation layer 36, the conductive layer 37, and the second isolation layer 38, which are arranged in sequence along the direction away from the source line SL. The conductive layer 37 is disposed on the inner side of the channel layer 34 to form a bypass resistor R connected in parallel with the memory transistor T. The existence of the bypass resistor R enables the memory string Str to always form a current path regardless of whether the memory cell T-R of the memory string Str is turned on or off. When performing a read operation on the memory cell T-R of the memory string Str, a read voltage only needs to be applied to the memory cell T-R to be read, and there is no need to apply a high voltage to the memory cells T-R of the same memory string Str. This can reduce the charge-discharge time of the memory cell T-R during the read operation, and reduce the dynamic power consumption generated by the read operation. This is conducive to improving the read speed of the memory cell T-R and extending the service life of the memory device.

In some embodiments, as shown in FIG. 1 to FIG. 5, the plurality of select lines SG include a source select line SSL, a plurality of word lines WL, and a drain select line DSL, which are arranged in sequence along the first direction Z. Each select line SG is disposed along a top surface parallel to the substrate 10, and arranged at intervals along the first direction Z. The channel structure 30 is disposed on the substrate 10 to vertically penetrate the plurality of select lines SG along the first direction Z. Each select line SG surrounds and covers a part of the circumferential surface of the channel structure 30.

In this embodiment, along the first direction Z, the lowermost select line SG among the plurality of select lines SG (the select line SG closest to the substrate 10) is the source select line SSL. A portion where the source select line SSL intersects the channel structure 30 constitutes a lower select transistor BM. The source select line SSL covers a channel of the lower select transistor BM and is connected to a control gate of the lower select transistor BM. The source select line SSL is configured to gate the turning-on or turning-off of the lower select transistor BM.

Along the first direction Z, the uppermost select line SG among the plurality of select lines SG (the select line SG farthest from the substrate 10) is the drain select line DSL. A portion where the drain select line DSL intersects the channel structure 30 constitutes an upper select transistor TM. The drain select line DSL covers a channel of the upper select transistor TM and is connected to a control gate of the upper select transistor TM. The drain select line DSL is configured to gate the turning-on and turning-off of the upper select transistor TM.

The plurality of select lines SG between the source select line SSL and the drain select line DSL are a plurality of word lines WL (WL₁, WL₂... WLₙ). A portion where the word line WL intersects the channel structure 30 constitutes a memory transistor T. The word line WL surrounds a channel of the memory transistor T and is connected to a control gate of the memory transistor T. As such, each word line WL can independently gate the corresponding memory transistor T, thereby implementing read and write operations on stored data.

In some embodiments, as shown in FIG. 1 to FIG. 5, a top surface of the first isolation layer 36 is lower than the plurality of word lines WL, a bottom surface of the second isolation layer 38 is higher than the plurality of word lines WL, and the conductive layer 37 is disposed between the top surface of the first isolation layer 36 and the bottom surface of the second isolation layer 38. Along the first direction Z, the first isolation layer 36 is disposed between the conductive layer 37 and the source line SL, to isolate the conductive layer 37 from the source line SL and prevent the conductive layer 37 and the source line SL from forming a conductive path. The second isolation layer 38 is disposed between the conductive layer 37 and the bit lines BL (BL₁, BL_{2,} BL₃), to isolate the conductive layer 37 from the bit lines BL (BL₁, BL₂, BL₃) and prevent the conductive layer 37 and the bit lines BL (BL₁, BL₂, BL₃) from forming a conductive path.

The first isolation layer 36 is located on the inner side of the channel layer 34 of the lower select transistor BM, and the second isolation layer 38 is located on the inner side of the channel layer 34 of the upper select transistor TM. The conductive layer 37 is disposed on an inner side of the channel layer 34 of the plurality of memory transistors T. In an aspect, the conductive layer 37 can form a bypass resistor R connected in parallel with the memory transistors T on the inner side of the memory transistors T in the same string. In another aspect, this prevents the conductive layer 37 from extending to the regions of the lower select transistor BM and the upper select transistor TM, avoids unnecessary interference to the lower select transistor BM or the upper select transistor TM, and prevents unexpected turning-on of the lower select transistor BM or the upper select transistor TM.

In some embodiments, as shown in FIG. 1 to FIG. 5, the source lines SL are connected to the channel structures 30 in a one-to-one correspondence. Alternatively, a group of adjacently arranged channel structures 30 are connected to the same source line SL. In this way, first, the number of memory strings Str processed by each source line SL can be reduced in a third direction X; second, in a second direction Y, each bit line BL (BL₁, BL₂, BL₃...) can be connected to a plurality of memory strings Str. A column of memory strings Str connected to the same bit line BL (BL₁, BL₂, BL₃) can be connected to a plurality of source lines SL. Parallel reading can be performed on the column of memory strings Str connected to the same bit line BL (BL₁, BL₂, BL₃), thereby improving the read bandwidth.

In an example, each channel structure 30 is correspondingly connected to one source line SL. As such, each source line SL independently operates and controls one memory string Str. This can improve the parallel read speed of the memory strings Str of the plurality of channel structures 30, and further improve the read bandwidth.

In another example, several adjacent channel structures 30 are connected to one source line SL. For example, two, three, four, or more adjacent channel structures 30 may be connected to one source line SL. As such, the manufacturing difficulty and production cost can be reduced.

In some embodiments, as shown in FIG. 1 to FIG. 5, the channel structures 30 are arranged in a plurality of columns along the second direction Y and in a plurality of rows along the third direction X. In other words, the channel structures 30 are arrayed along the second direction Y and the third direction X. The second direction Y and the third direction X are parallel to the substrate 10, and the second direction Y intersects the third direction X. In this embodiment, the second direction Y is perpendicular to the third direction X.

In this embodiment, the source lines SL are also arrayed along the second direction Y and the third direction X. This facilitates the layout of the source lines SL, and realizes the one-to-one correspondence connection between the source lines SL and the channel structures 30. Alternatively, a group of adjacently arranged channel structures 30 are connected to the same source line SL.

In an embodiment, a memory device is provided by the present disclosure. As shown in FIG. 1 to FIG. 5, the memory device includes a substrate 10, a source line SL, a memory string Str, a plurality of word lines WL, a source select line SSL, a drain select line DSL, and a bit line BL. A driver circuit layer 11 may be integrated on the substrate 10. The driver circuit layer 11 is configured to provide a voltage or current signal to the memory device to control a write or read operation of the memory device. The source line SL is disposed on the substrate 10 and connected to the substrate 10. The memory string Str is disposed on a side of the source line SL away from the substrate 10, and the memory string Str is connected to the substrate 10 through the source line SL. The memory string Str includes a lower select transistor BM, a plurality of memory cells T-R, and an upper select transistor TM, which are arranged in sequence along a first direction Z perpendicular to the substrate 10. Each memory cell T-R includes a memory transistor T and a bypass resistor R connected in parallel with the memory transistor T. The plurality of word lines WL are arranged at intervals along the first direction Z, and each word line WL is connected to a control gate of the memory transistor T disposed on the same layer. The source select line SSL is disposed below the plurality of word lines WL, and the source select line SSL is connected to a control gate of the lower select transistor BM. The drain select line DSL is disposed above the plurality of word lines WL, and the drain select line DSL is connected to a control gate of the upper select transistor TM. The bit line BL is disposed on a side of the upper select transistor TM away from the substrate 10, and the bit line BL is connected to the upper select transistor TM of at least one memory string Str.

In the memory device of this embodiment, by improving the structure of the memory cell T-R, the memory transistor T is connected in parallel with the bypass resistor R, so that regardless of whether the memory transistor T of the memory cell T-R is turned on or off, the memory string Str where the memory cell T-R is located can always form a current path. When performing a read operation on the memory cell T-R of the memory string Str, a read voltage only needs to be applied to the memory cell T-R to be read, and there is no need to apply a high voltage to the memory cells T-R of the same memory string Str. This can reduce the charge-discharge time of the memory cell T-R during the read operation, and reduce the dynamic power consumption generated by the read operation. This is conducive to improving the read speed of the memory cell T-R and extending the service life of the memory device.

In some embodiments, a resistance value R of the bypass resistor R is greater than a channel equivalent resistance Rₒₙ of the memory transistor T when turned on, and less than a channel equivalent resistance R_{off} of the memory transistor T when turned off.

In the memory device of this embodiment, the switching of the memory transistor T can be controlled by controlling a voltage V_{WL} of the word line WL and a threshold voltage V_{T} of the memory transistor T. When the voltage V_{WL} of the word line WL is greater than V_{T}, the memory transistor T is turned on, an equivalent resistance of the memory cell T-R is approximate to the channel equivalent resistance Rₒₙ of the memory transistor T when turned on, and current mainly passes through the memory transistor T. When V_{WL} is less than V_{T}, the memory transistor T is turned off, the equivalent resistance of the memory cell T-R is approximate to the resistance value of the bypass resistor R, and current mainly passes through the bypass resistor R. Therefore, regardless of whether the memory transistor T is turned on or turned off, the memory string Str where the memory cell T-R is located can always form a current path. Further, when performing a read operation on the memory cell T-R of the memory string Str, only a read voltage needs to be applied to the memory cell T-R to be read, and there is no need to apply a high voltage to the memory cells T-R of the same memory string Str.

In some embodiments, as shown in FIG. 1 to FIG. 5, the source lines SL are connected to the memory strings Str in a one-to-one correspondence. Alternatively, a group of adjacently arranged memory strings Str are connected to the same source line SL. As such, the number of memory strings Str processed by each source line SL can be reduced. Since each bit line BL (BL₁, BL_{2,} BL₃) can be connected to a plurality of channel structures 30, parallel reading of the memory strings Str of the plurality of channel structures 30 can be realized, thereby improving the read bandwidth. In an example, each channel structure 30 is correspondingly connected to one source line SL. In another example, several adjacent channel structures 30 are connected to one source line SL.

In some embodiments, as shown in FIG. 1 to FIG. 5, the memory strings Str are arranged in a plurality of columns along a second direction Y parallel to the substrate 10. The plurality of columns of memory strings Str are arranged at intervals along a third direction X, where the third direction X is parallel to the substrate 10 and intersects the second direction Y. The bit lines BL (BL₁, BL_{2,} BL₃) extend on the memory strings Str along the second direction Y, and each bit line BL is connected to each column of memory strings Str.

The memory device of this embodiment has good scalability. The number of memory cells T-R can be increased and/or the layout of the word lines WL, source lines SL, bit lines BL, etc., can be adjusted, to expand the storage capacity to meet different application requirements.

In the memory device of the embodiment of the present disclosure, the read operation of each memory string Str is independent, and the storage state can be determined by detecting an accumulated voltage drop ΔV of each memory string Str. Parallel reading of a plurality of memory pages can be realized, which significantly improves the bandwidth and efficiency of the read operation of the memory device.

For example, in some embodiments, when performing a read operation on the memory device, a read voltage V_{read} is applied to the word line WL corresponding to the selected memory cell T-R. A turn-off voltage Vₛₕᵤₜ is applied to the word line WL corresponding to the unselected memory cell T-R, to prevent the unselected memory cell T-R from interfering with the selected memory cell T-R during the read process. A read current I_{ref} is provided to the memory string Str from the source line SL. A voltage value of the read voltage Vread is between a high threshold voltage V_{T,H} when the memory transistor T is written with logic “1” and a low threshold voltage V_{T,L} when the memory transistor T is written with logic “0”.

In this embodiment, the turn-off voltage Vₛₕᵤₜ is less than the read voltage V_{read}, the high threshold voltage V_{T,H}, and the low threshold voltage V_{T,L}, to ensure that the memory transistor T remains turned off regardless of whether the threshold voltage of the memory transistor T is high or low.

By detecting the accumulated voltage drop ΔV of the memory string Str, when the memory transistor T is in a turned-on or turned-off state, the equivalent resistance of the memory cell T-R has a significant difference, and the difference of the equivalent resistance is approximately R. When the memory transistor T is turned on or turned off, the detected accumulated voltage drop ΔV of the memory string Str has a difference of approximately I_{ref}·R. The number of turned-off memory transistors T in the selected memory cell T-R can be calculated based on the difference between the actual accumulated voltage drop of the memory string Str and the accumulated voltage drop of the unselected memory cell T-R.

When performing a read operation on the memory device in this embodiment, the turn-off voltage Vₛₕᵤt is applied to the unselected memory cell T-R, and there is no need to apply a high voltage to the unselected memory cell T-R to turn on the memory transistor T to avoid interference to the read operation. The read operation can be completed by applying the read voltage V_{read} and the read current I_{ref}, thereby reducing power consumption, delay, and potential interference.

The above embodiments are only implementations for performing a read operation on the memory device of the present disclosure, and do not constitute a limitation to the memory device of the present disclosure.

In some other implementations, when performing a read operation on the memory device of the present disclosure, a read voltage V_{read} can be applied to the word line WL corresponding to the selected memory cell T-R. A turn-on voltage Vₚₐₛₛ is applied to the word line WL corresponding to the unselected memory cell T-R.

In this embodiment, V_{T,L} < V_{read} < V_{T,H} < Vₚₐₛₛ. That is, when and only when the threshold voltage of the memory transistor T is equal to V_{T,H} and the word line voltage is equal to V_{read}, the memory transistor T in the memory cell T-R is in an off state and generates a voltage drop across two sides of the memory cell T-R. In other cases, the memory transistor T is turned on.

The number of turned-off memory transistors T in the selected memory cell T-R can be directly calculated by detecting the accumulated voltage drop ΔV of the memory string Str.

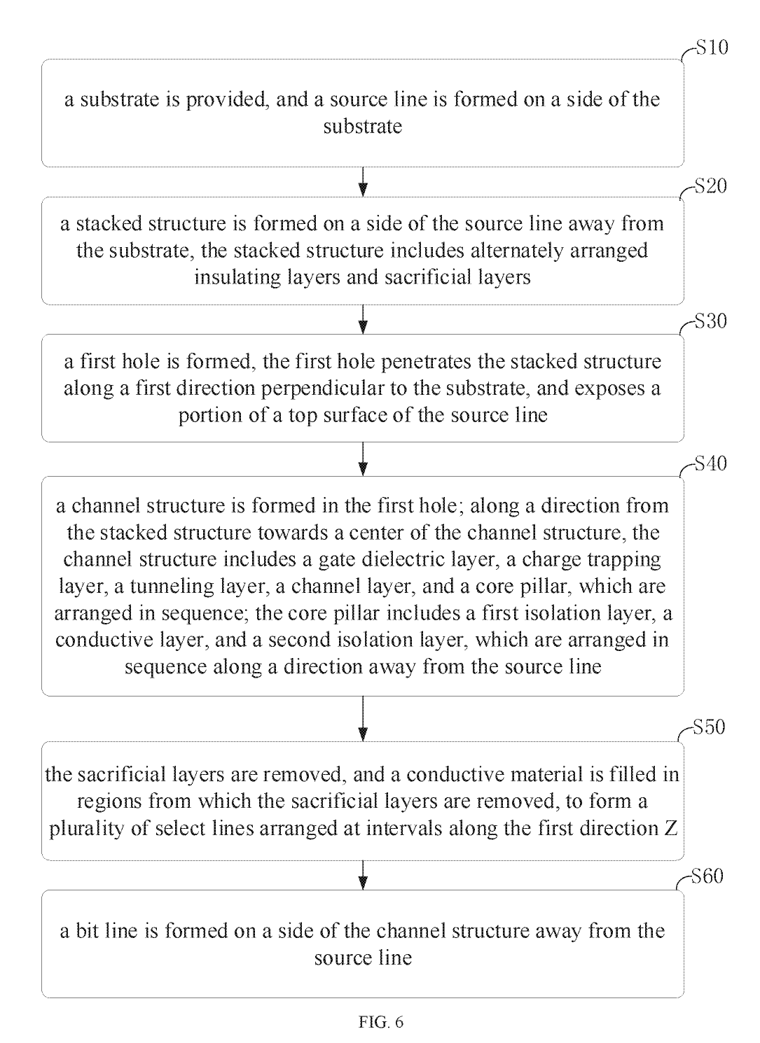

According to an embodiment, a manufacturing method for a memory device is provided by the present disclosure. As shown in FIG. 6, the manufacturing method for the memory device includes the following Step S10 to Step S60.

At Step S10, a substrate 10 is provided, and a source line SL is formed on a side of the substrate 10.

At Step S20, a stacked structure 20 is formed on a side of the source line SL away from the substrate 10. The stacked structure 20 includes alternately arranged insulating layers 21 and sacrificial layers 22.

At Step S30, a first hole 23 is formed. The first hole 23 penetrates the stacked structure 20 along a first direction Z perpendicular to the substrate 10, and exposes a portion of a top surface of the source line SL.

At Step S40, a channel structure 30 is formed in the first hole 23. Along a direction from the stacked structure 20 towards a center of the channel structure 30, the channel structure 30 includes a gate dielectric layer 31, a charge trapping layer 32, a tunneling layer 33, a channel layer 34, and a core pillar 35, which are arranged in sequence. The core pillar 35 includes a first isolation layer 36, a conductive layer 37, and a second isolation layer 38, which are arranged in sequence along a direction away from the source line SL.

At Step S50, the sacrificial layers 22 are removed, and a conductive material is filled in regions from which the sacrificial layers 22 are removed, to form a plurality of select lines SG arranged at intervals along the first direction Z.

At Step S60, a bit line BL is formed on a side of the channel structure 30 away from the source line SL.

In the manufacturing method for the memory device of this embodiment, the core pillar 35 of the channel structure 30 includes the first isolation layer 36, the conductive layer 37, and the second isolation layer 38, which are arranged in sequence along the direction away from the source line SL. The conductive layer 37 is disposed on the inner side of the channel layer 34 to form a bypass resistor R connected in parallel with the memory transistor T. The existence of the bypass resistor R enables the memory string Str to always form a current path regardless of whether the memory cell T-R of the memory string Str is turned on or turned off. When performing a read operation on the memory cell T-R of the memory string Str, a high voltage only needs to be applied to the memory cell T-R to be read, and there is no need to apply a high voltage to the memory cells T-R of the same memory string Str. This can reduce the charge-discharge time of the memory cell T-R during the read operation, and reduce the dynamic power consumption generated by the read operation. This is conducive to improving the read speed of the memory cell T-R and extending the service life of the memory device. The memory device of this embodiment can perform a read operation on a single memory cell T-R in the memory string Str, and perform fine control on the single memory cell T-R, thereby improving the operation flexibility of the memory device.

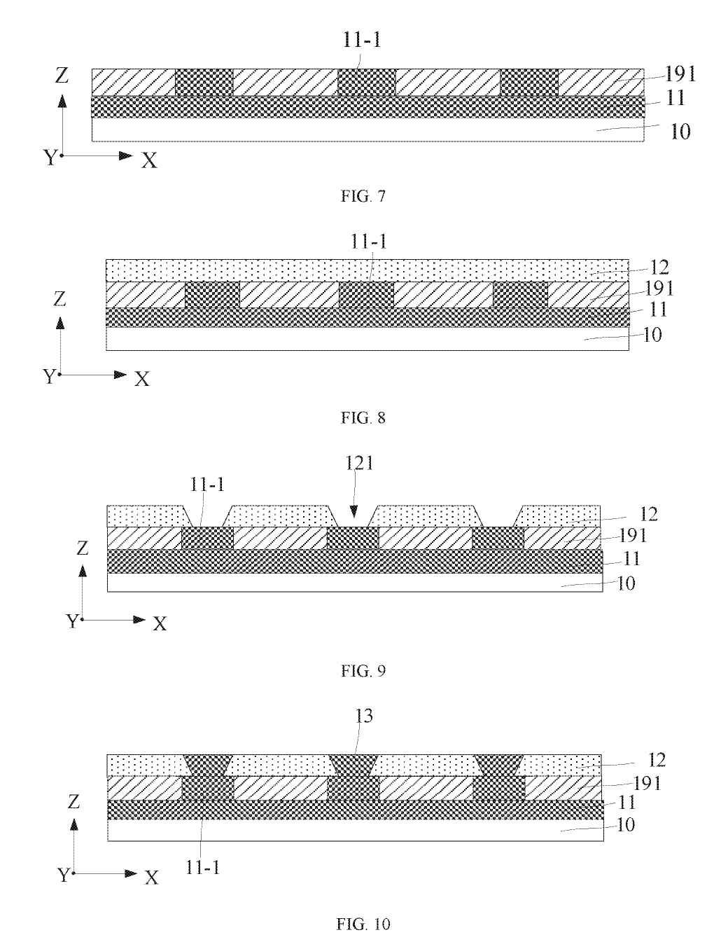

At Step S10, as shown in FIG. 7, the substrate 10 may be a semiconductor substrate. The semiconductor substrate may include a silicon substrate, a germanium (Ge) substrate, a silicon germanium (SiGe) substrate, a silicon-on-insulator (SOI) substrate, a germanium-on-insulator (GOI) substrate, or the like. Ions may be doped in the semiconductor substrate. For example, the semiconductor substrate may be a P-type doped substrate or an N-type doped substrate. In this embodiment, the substrate is a silicon crystalline substrate.

As shown in FIG. 7, a driver circuit layer 11 can be formed on the substrate 10 provided in this embodiment. For example, the driver circuit layer 11 can be formed on the substrate 10 by using CMOS Under Array (CUA). The driver circuit layer 11 is configured to implement functions of a peripheral auxiliary circuit, such as detection, amplification, and conversion. In this embodiment, the driver circuit layer 11 is configured to provide a voltage or current signal to the memory device to control a write or read operation of the memory device.

CUA is a design method for placing peripheral circuits (such as page buffers, read amplifiers, charge pumps, etc.) of most NAND chips under the vertical stack of memory cells. This layout greatly saves the wafer die space, so that more area can be used for arrays of the memory cells, thereby improving storage density and performance.

As shown in FIG. 7, source contacts 11-1 are formed on the driver circuit layer 11. The source contacts 11-1 are configured to be connected to the source lines SL. A first dielectric layer 191 is filled between the source contacts 11-1.

In this embodiment, before forming the source line SL on one side of the substrate 10, the method further includes: forming a connection plug 13 on the source contact 11-1. The connection plug 13 is configured to connect the source contact 11-1 and the source line SL.

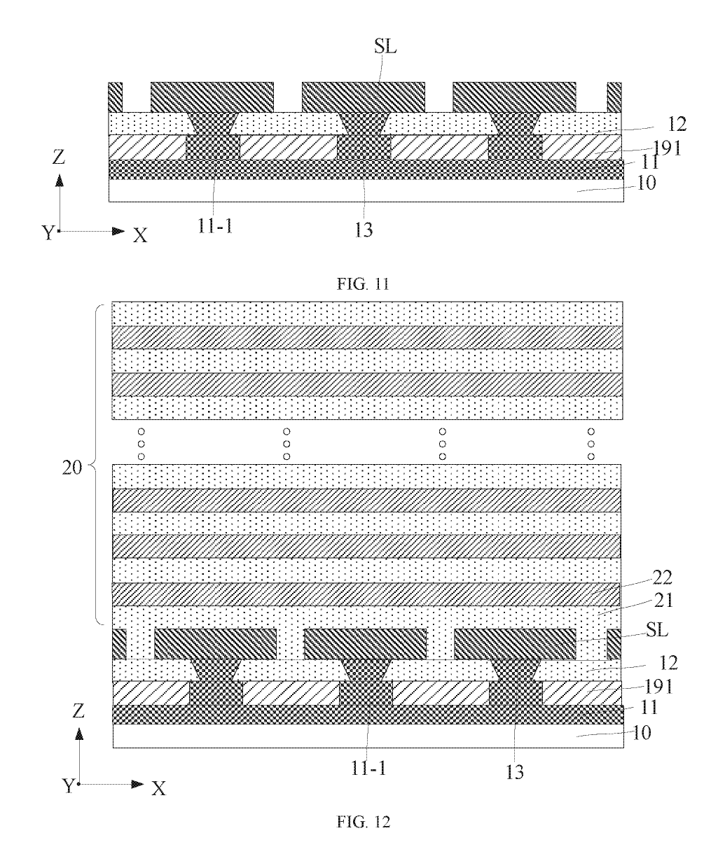

As shown in FIG. 8, any one process of chemical vapor deposition (CVD), physical vapor deposition (PVD), atomic layer deposition (ALD), plasma enhanced chemical vapor deposition (PECVD), or sputtering may be selected to deposit and form a second dielectric layer 12. The second dielectric layer 12 covers the top surfaces of the first dielectric layer 191 and the source contacts 11-1. Then, as shown in FIG. 9, the second dielectric layer 12 is etched to form a first via hole 121 penetrating the second dielectric layer 12. The first via hole 121 correspondingly exposes the source contact 11-1. Next, as shown in FIG. 10, a conductive material can be filled in the first via hole 121 by using any of the above depositions to form the connection plug 13.

For example, the material of the second dielectric layer 12 may include at least one of silicon oxide, silicon nitride, silicon oxynitride, or silicon oxycarbide.

For example, the material of the connection plug 13 may include a metal material such as tungsten and copper.

In this embodiment, the source line SL can be formed on one side of the substrate 10 by using the following implementations:

Any of the above depositions may be used to deposit and form a semiconductor layer (not shown in the drawings). The semiconductor layer covers the top surfaces of the second dielectric layer and the connection plug 13. Then, a photoresist mask (not shown in the drawings) is formed on the semiconductor layer. As shown in FIG. 11, the semiconductor layer is etched according to the photoresist mask to form a plurality of independently arranged source lines SL. The source lines SL are connected to the connection plugs 13 in a one-to-one correspondence.

For example, a material of the semiconductor layer may include materials such as silicon, germanium, and silicon germanium. Ions may be doped in the semiconductor layer. For example, the semiconductor may be P-type doped or N-type doped.

For example, the semiconductor layer may be etched by using a dry process. For example, a dry etching such as reactive ion etching (RIE) or inductively coupled plasma (ICP) etching may be used.

In this embodiment, as shown in FIG. 11, the source lines SL are arranged in an array along a second direction Y and a third direction X parallel to the substrate 10, and the second direction Y is perpendicular to the third direction X.

At Step S20, as shown in FIG. 12, any one process of chemical vapor deposition, physical vapor deposition, atomic layer deposition, or sputtering can be selected to alternately deposit the insulating layers 21 and the sacrificial layers 22, to form the stacked structure 20 on the substrate 10. The sacrificial layer 22 has a high etching ratio relative to the insulating layer 21. For example, a material of the insulating layer 21 may include silicon oxide. A material of the sacrificial layer 22 may include silicon nitride.

In this embodiment, both a bottom layer and a top layer of the stacked structure 20 are the insulating layers 21. As such, the bottom insulating layer 21 of the stacked structure 20 is configured to electrically isolate the source lines SL from each other, and electrically isolate the source lines SL from the subsequently formed memory cells T-R, to ensure the safety of the memory device and improve the electrical performance thereof. The top insulating layer 21 of the stacked structure 20 is configured to provide a process plane, to facilitate the execution of subsequent processes.

The number of stacked layers of the stacked structure 20 can be flexibly adjusted according to manufacturing requirements, which is not limited in this embodiment.

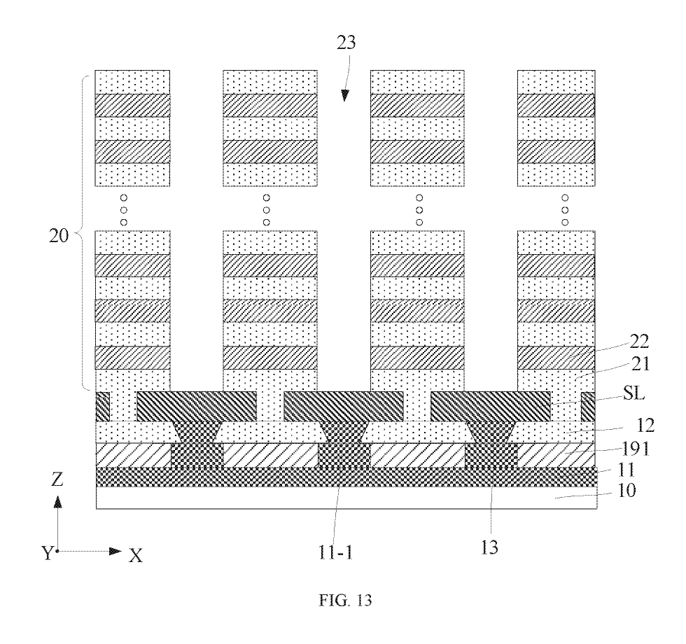

At Step S30, in this embodiment, a first mask layer (not shown in the drawings) is formed on the top surface of the stacked structure 20. As shown in FIG. 13, the stacked structure 20 is etched according to the first mask layer until a portion of the top surface of the source line SL is exposed, to form the first hole 23 penetrating the stacked structure 20. The bottom surface of the first hole 23 exposes a portion of the top surface of the source line SL.

In some embodiments, as shown in FIG. 13, a plurality of first holes 23 are formed in the stacked structure 20, and the plurality of first holes 23 are arranged in an array along the second direction Y and the third direction X.

In an example, each first hole 23 is correspondingly formed on each source line SL, and the source lines SL are connected to the channel structures 30 in a one-to-one correspondence. In another example, a plurality of first holes 23 are formed on each source line SL, and a group of adjacently arranged channel structures 30 are connected to the same source line SL.

At Step S40, forming the channel structure 30 in the first hole 23 includes the following Step S41.

At Step S41, a gate dielectric layer 31, a charge trapping layer 32, a tunneling layer 33, and a channel layer 34 that sequentially cover an inner sidewall of the first hole 23 are formed. At least a portion of a bottom surface of the channel layer 34 is in contact with the source line SL.

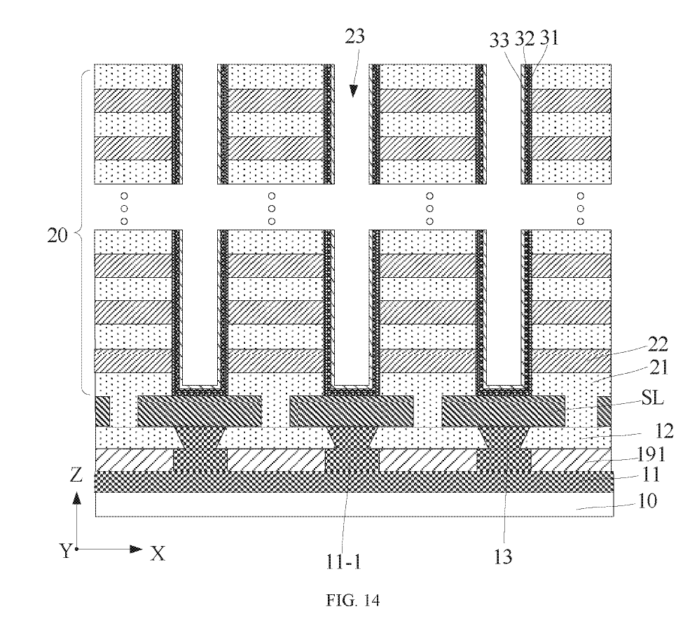

As shown in FIG. 14, the gate dielectric layer 31, the charge trapping layer 32, and the tunneling layer 33 may be sequentially deposited and formed by a chemical vapor deposition process or an atomic layer deposition process. The gate dielectric layer 31, the charge trapping layer 32, and the tunneling layer 33 sequentially cover a sidewall and a bottom surface of the first hole 23.

A material of the gate dielectric layer 31 includes at least one of silicon oxide, silicon nitride, or silicon oxynitride. A material of the charge trapping layer 32 is silicon nitride, and the charge trapping layer 32 is configured to trap charges. A material of the tunneling layer 33 includes silicon oxide or silicon oxynitride.

Then, the gate dielectric layer 31, the charge trapping layer 32, and the tunneling layer 33 on the bottom surface of the first hole 23 are removed by etching.

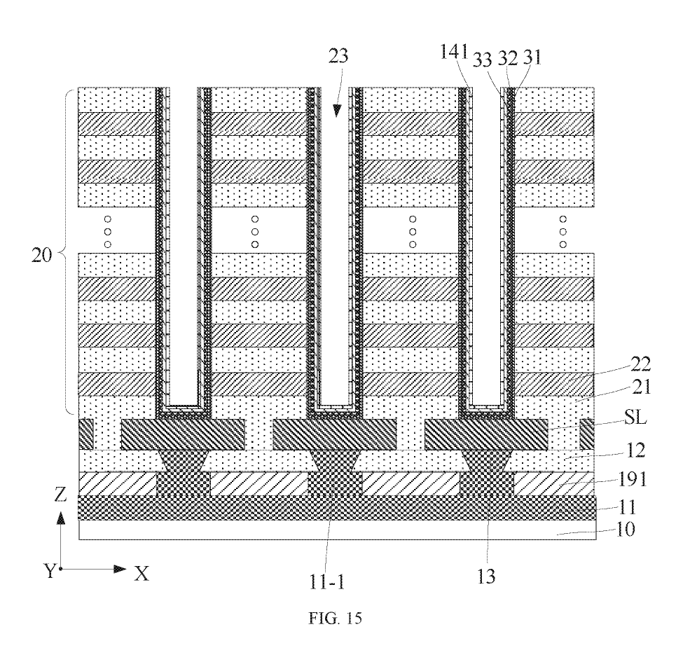

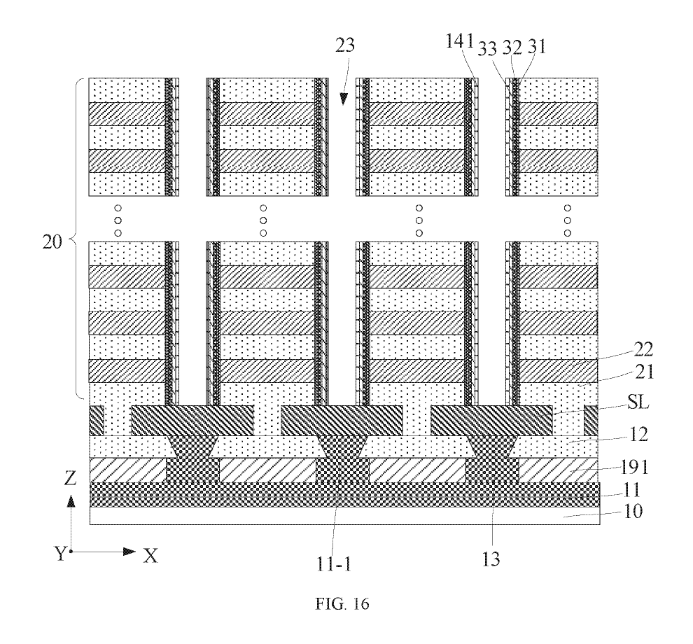

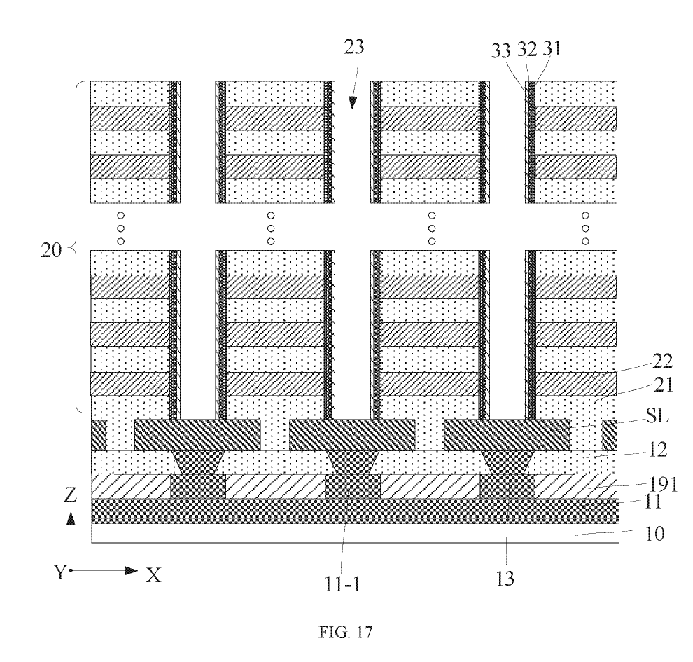

In this embodiment, as shown in FIG. 15, a protective layer 141 may be deposited and formed by atomic layer deposition. The protective layer 141 covers an inner sidewall and a bottom surface of the tunneling layer 33, and the protective layer 141 is configured to protect the gate dielectric layer 31, the charge trapping layer 32, and the tunneling layer 33, which are located on the sidewall of the first hole 23. As shown in FIG. 16, anisotropic dry etching is then used to etch and remove the protective layer 141, the tunneling layer 33, the charge trapping layer 32, and the gate dielectric layer 31 on the bottom surface of the first hole 23. As shown in FIG. 17, wet etching is then used to etch and remove all the protective layer 141, to expose the tunneling layer 33 located on the sidewall of the first hole 23.

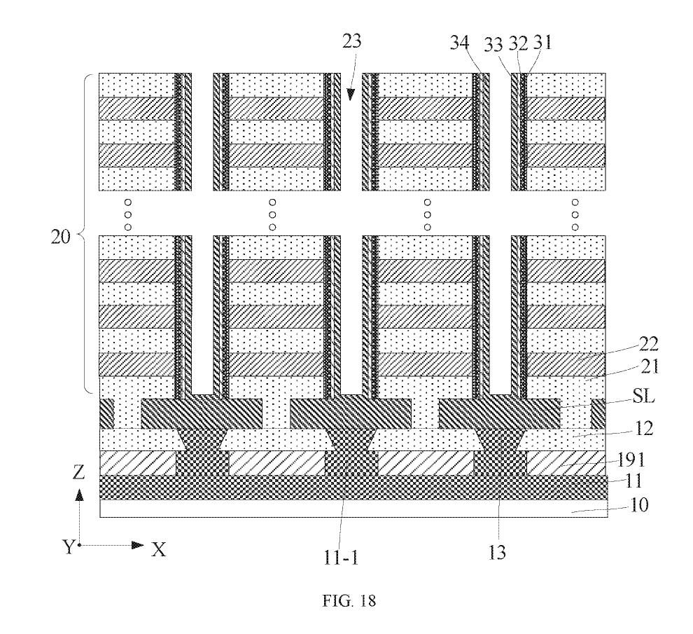

Next, as shown in FIG. 18, the channel layer 34 may be formed by plasma-enhanced chemical vapor deposition. The channel layer 34 covers the source line SL exposed at the bottom surface of the first hole 23 and the inner sidewall of the tunneling layer 33. As such, the contact area between the channel layer 34 and the source line SL is larger, which can improve the response rate of the source line SL controlling the channel structure 30. A material of the channel layer 34 includes a semiconductor material (such as polysilicon) or a metal oxide material (such as IGZO), etc.

IGZO is an amorphous or microcrystalline material. The molecular structure of IGZO is relatively uniform, the processing temperature is low, and no obvious grain boundary exists. Using IGZO as the channel layer 34 can reduce the processing temperature, simplify the production process, and reduce the cost. Since IGZO has no obvious grain boundaries, the carrier mobility of the channel layer 34 can also be improved, which helps to improve the switching speed and reliability of the transistor.

For example, the material of the metal oxide may be indium gallium zinc oxide (IGZO). The material of the metal oxide may also be ITO, IWO, ZnOₓ, InOₓ, In₂O₃, InWO, SnO₂, TiOₓ, InSnOₓ, ZnₓO_{y}N_{z}, MgₓZn_{y}O_{z}, InₓZn_{y}O_{z}, InₓGa_{y}Zn_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{d}, SiₓIn_{y}Zn_{z}Oₐ, ZnₓSn_{y}O_{z}, AlₓZn_{y}Sn_{z}Oₐ, GaₓZn_{y}Sn_{z}Oₐ, ZrₓZn_{y}Sn_{z}Oₐ, InGaSiO, IAZO, IGO, IZO (indium-zinc-oxide), IZOx, or other materials.

At Step S42, a first isolation layer 36, a conductive layer 37, and a second isolation layer 38 are formed on an inner side of the channel layer 34. The first isolation layer 36, the conductive layer 37, and the second isolation layer 38 are arranged in sequence along a direction away from the substrate 10.

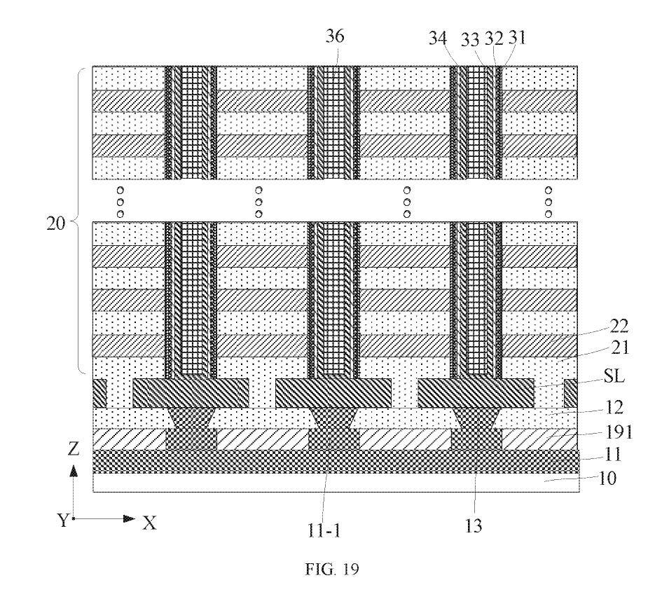

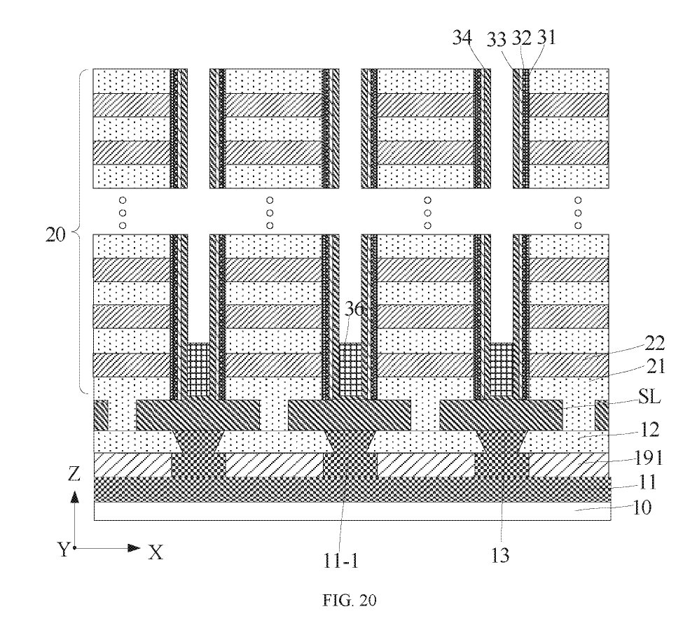

First, as shown in FIG. 19, the first isolation layer 36 may be deposited by chemical vapor deposition or plasma-enhanced chemical vapor deposition. The first isolation layer 36 covers the inner side of the channel layer 34 and fills at least part of the first hole 23. As shown in FIG. 20, the first isolation layer 36 is etched back so that the first isolation layer 36 is located at the bottom of the first hole 23.

For example, a material of the first isolation layer 36 may include at least one of silicon oxide, silicon nitride, or silicon oxynitride.

The first isolation layer 36 may include a single-layer structure or a multi-layer structure. In this embodiment, the first isolation layer 36 includes silicon oxide. As such, the effect of electrical isolation of the first isolation layer 36 is better.

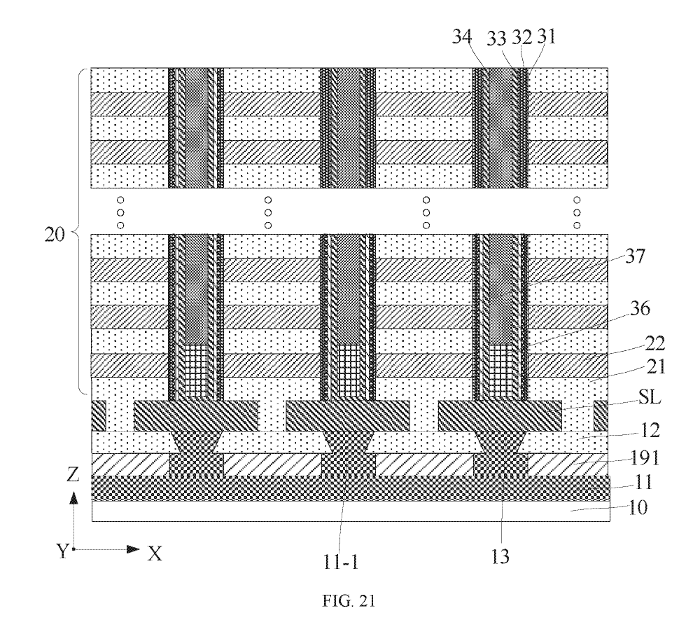

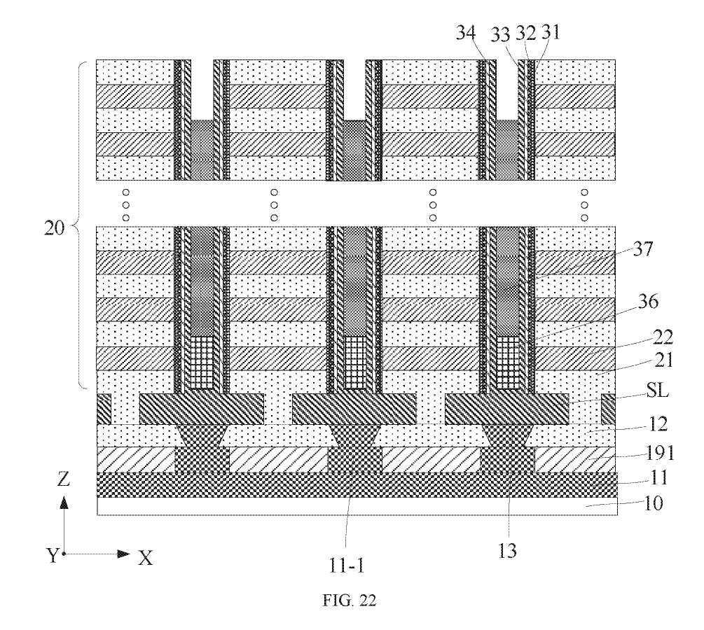

Then, as shown in FIG. 21, the conductive layer 37 is deposited by atomic layer deposition or chemical vapor deposition. The conductive layer 37 covers the top surface of the first isolation layer 36 and fills the unfilled part of the first hole 23. As shown in FIG. 22, the conductive layer 37 is etched back so that the conductive layer 37 is located in the first hole 23.

For example, a material of the conductive layer 37 may include at least one of zinc oxide (ZnO), vanadium oxide (VOₓ), or doped polysilicon. The material of the conductive layer 37 may also include conductive metals, for example, at least one of tungsten, titanium, and tantalum.

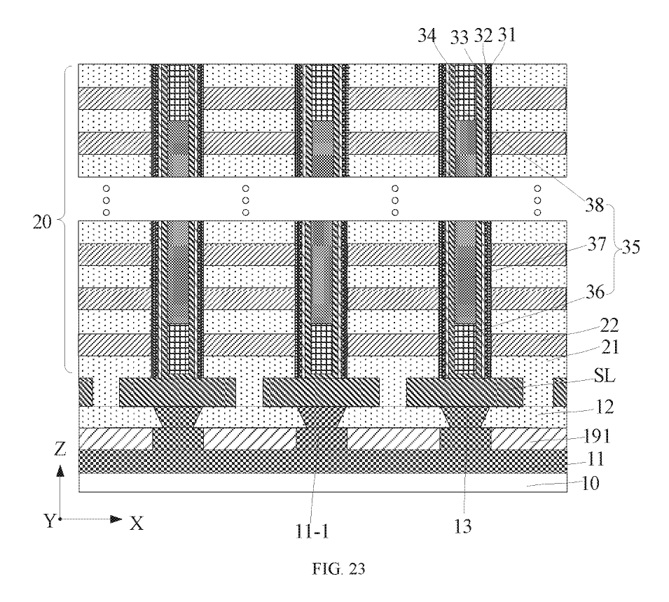

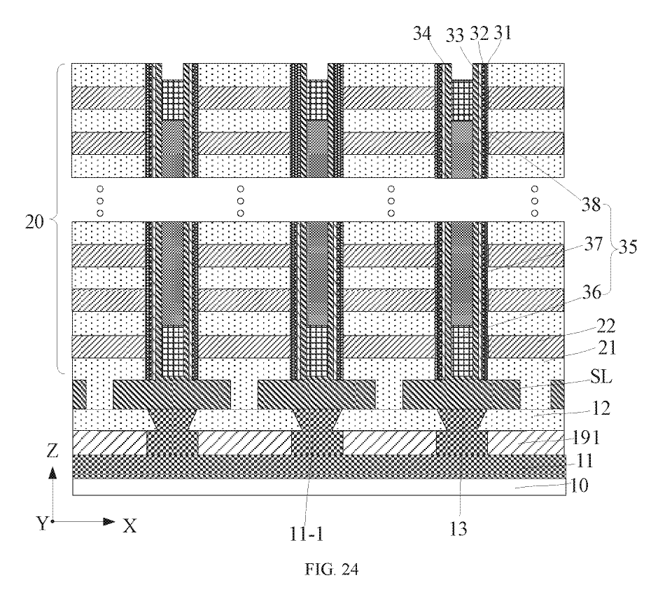

Next, as shown in FIG. 23 and FIG. 24, the second isolation layer 38 may be deposited by chemical vapor deposition or plasma-enhanced chemical vapor deposition. The second isolation layer 38 covers the conductive layer 37 and fills the unfilled part of the first hole 23.

The second isolation layer 38 may include a single-layer structure or a multi-layer structure. In this embodiment, the second isolation layer 38 includes a silicon oxide layer, a silicon nitride layer, and a silicon oxide layer, which are sequentially stacked. As such, the effect of electrical isolation of the second isolation layer 38 is better.

At Step S50, the sacrificial layers 22 are removed, and a conductive material is filled in the regions from which the sacrificial layers 22 are removed to form a plurality of select lines SG arranged at intervals along the first direction Z. This process may use the following implementations.

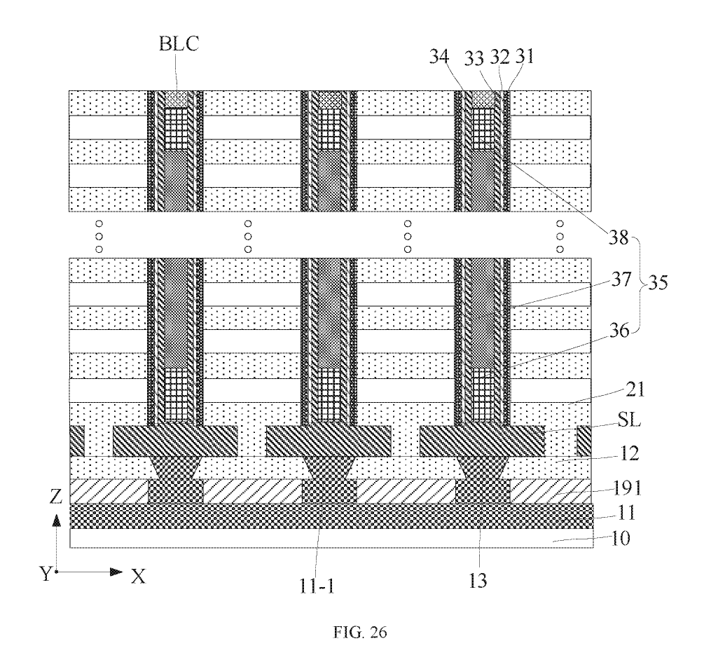

As shown in FIG. 26, a second mask layer (not shown in the drawings) is formed on the top surface of the stacked structure 20. The stacked structure 20 is etched according to the second mask layer to form a second hole (not shown in the drawings) penetrating the stacked structure 20. The second hole is staggered from the first hole 23.

Then, an etchant is injected into the second hole to dissolve and remove all the sacrificial layers 22. In this embodiment, hot phosphoric acid may be selected as the etchant.

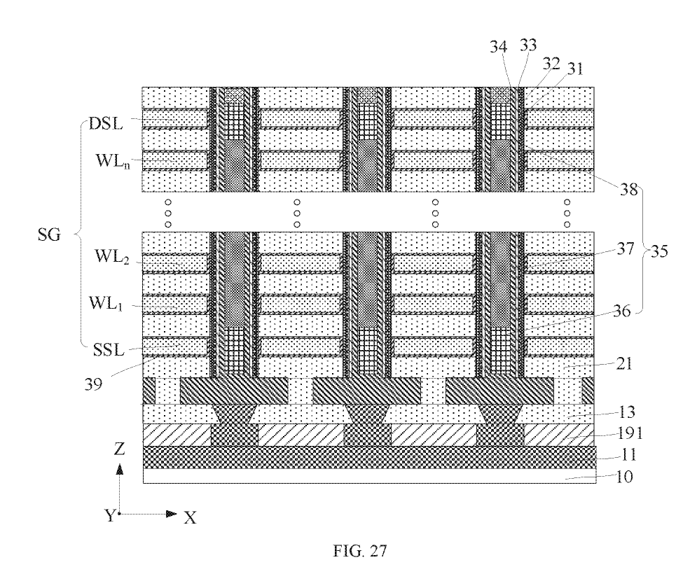

Next, as shown in FIG. 27, a high-k dielectric material layer 39 may be formed by atomic layer deposition or chemical vapor deposition. The high-k dielectric material layer 39 covers the exposed surfaces of the insulating layers 21 and the exposed surfaces of the gate dielectric layer 31.

For example, a material of the high-k dielectric material layer 39 includes a high-permittivity material (High-K dielectric), such as at least one of hafnium oxide (HfO₂), zirconium oxide (ZrO₂), aluminum oxide (AlOₓ), titanium oxide (TiO₂), and tantalum oxide (TaOx).

Next, as shown in FIG. 27, a conductive material may be deposited by a physical vapor deposition process, a plasma enhanced chemical vapor deposition process, or an atomic layer deposition process to cover the high-k dielectric material layer 39 and fill the regions from which the sacrificial layers 22 are removed, to form a plurality of select lines SG arranged at intervals along the first direction Z.

For example, a material of the select line SG may include one or more of vanadium (V), niobium (Nb), ruthenium (Ru), tungsten (W), tantalum (Ta), tantalum nitride (TaN), titanium (Ti), titanium nitride (TiN), hafnium (Hf), iridium (Ir), manganese (Mn), zinc (Zn), platinum (Pt), palladium (Pd), copper (Cu), and an alloy of some of these materials.

In this embodiment, as shown in FIG. 27, after forming the plurality of select lines SG, the conductive material and the high-k dielectric material layer 39 in the second hole are removed by etching. An insulating material is deposited into the second hole to form an insulating pillar. A material of the insulating pillar may include at least one of silicon oxide, silicon nitride, or silicon oxynitride.

At Step S60, the bit line BL is formed on the side of the channel structure 30 away from the source line SL. This process may adopt the following implementations.

First, as shown in FIG. 23 and FIG. 24, the second isolation layer 38 is etched back, so that the top surface of the second isolation layer 38 is lower than the top surface of the first hole 23, and the second isolation layer 38 exposes a part of the inner sidewall of the channel layer 34.

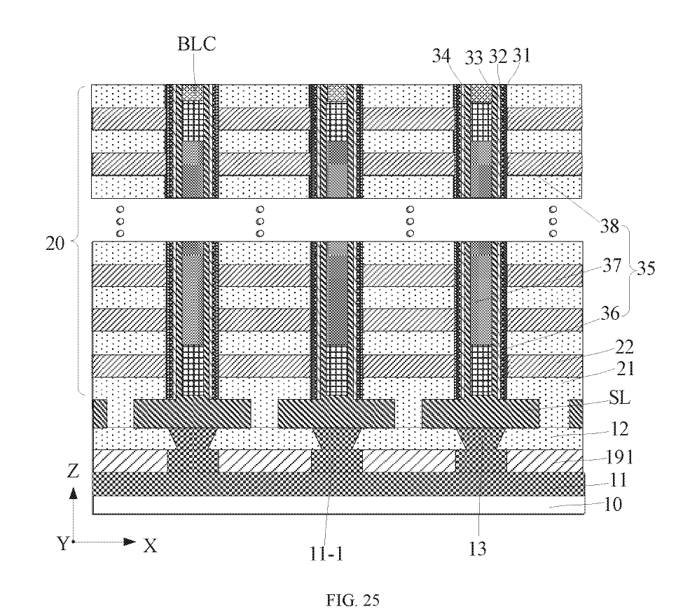

Then, as shown in FIG. 25, a contact layer (not shown in the drawings) may be deposited and formed by an atomic layer deposition process. The contact layer covers the part of the inner sidewall of the channel layer 34 exposed by the second isolation layer 38 and fills the unfilled region of the first hole 23. The contact layer also covers the top surface of the stacked structure 20. The contact layer covering the top surface of the stacked structure 20 is removed by etching, and a bit line contact BLC is formed in the first hole 23. The bit line contact BLC is configured to reduce the contact resistance between the bit line BL and the channel layer 34, which is conducive to improving the response speed of the bit line BL and the electrical performance of the memory device.

For example, a material of the bit line contact BLC may include silicon.

Next, as shown in FIG. 1 to FIG. 5, a bit line conductive layer may be deposited by physical vapor deposition, plasma-enhanced chemical vapor deposition, or atomic layer deposition. The bit line conductive layer covers the top surface of the bit line contact and the top surface of the stacked structure 20. The bit line conductive layer is patterned and etched to form bit lines BL. The bit lines BL extend along the second direction Y and are arranged at intervals along the third direction X.

For example, a material of the bit line BL may include tungsten, titanium, and the like.

Although the steps in the process described in FIG. 6 and the foregoing are sequentially displayed according to the arrows or the sequence of steps, these steps are not necessarily executed in the order indicated by the arrows. Unless explicitly stated herein, the execution of these steps is not strictly limited to the order, and these steps may be executed in other orders. Moreover, at least a part of the steps in the process described in FIG. 7, and the foregoing, may include a plurality of steps or a plurality of stages. These steps or stages are not necessarily executed and completed at the same time, but may be executed at different times. The execution order of these steps or stages is not necessarily sequential, but may be executed in turn or alternately with other steps, or at least a part of the steps or stages in other steps.

The sequence of manufacturing the memory cells, word lines, bit lines, and source lines in the foregoing embodiments may be arbitrarily adjusted or may be combined with each other. Therefore, for those skilled in the art, combining and/or adjusting the manufacturing processes of any plurality of the memory cells, word lines, bit lines, and source lines without creative efforts shall fall within the protection scope of the embodiments of the present disclosure.

In some embodiments, an electronic device is provided, which includes the memory device as described in any of the embodiments of the present disclosure. The electronic device is, for example, but not limited to, suitable types of electronic products such as consumer electronic products, home electronic products, vehicle-mounted electronic products, and financial terminal products. Consumer electronic products are, for example, mobile phones, tablet computers, notebook computers, desktop monitors, all-in-one computers, and the like. Home electronic products are, for example, smart door locks, televisions, refrigerators, wearable devices, and the like. Vehicle-mounted electronic products are, for example, vehicle-mounted navigators, vehicle-mounted DVDs, and the like. Financial terminal products are, for example, ATMs, self-service business terminals, and the like.

Those of ordinary skill in the art can understand that all or part of the processes in the methods of the above embodiments can be implemented by a computer program instructing relevant hardware. The computer program may be stored in a non-volatile computer-readable storage medium, and when executed, the computer program may include the processes of the above method embodiments. Any reference to memory, database, or other media used in the embodiments provided by the present disclosure may include at least one of non-volatile memory and volatile memory. Non-volatile memory may include read-only memory (ROM), magnetic tape, floppy disk, flash memory, optical memory, high-density embedded non-volatile memory, resistive random access memory (ReRAM), magneto-resistive random access memory (MRAM), ferroelectric random access memory (FRAM), phase change memory (PCM), graphene memory, and the like. Volatile memory may include random access memory (RAM), external cache memory, and the like. The databases involved in the embodiments provided by the present disclosure may include at least one of relational databases and non-relational databases. Non-relational databases may include distributed databases based on blockchain, etc., and are not limited thereto. The processors involved in the embodiments provided by the present disclosure may be general-purpose processors, central processing units, graphics processing units, digital signal processors, programmable logic devices, data processing logic devices based on quantum computing, etc., and are not limited thereto. The technical features of the above embodiments may be combined arbitrarily. For brevity of description, all possible combinations of the technical features in the above embodiments are not described. However, as long as there is no contradiction in the combination of these technical features, it shall be considered as falling within the scope recorded in this specification.

The above embodiments are for illustrative purposes only and do not imply a limitation to the present disclosure.

The technical features of the above embodiments may be combined arbitrarily. For brevity of description, all possible combinations of the technical features in the above embodiments are not described. However, as long as there is no contradiction in the combination of these technical features, it shall be considered as falling within the scope recorded in this specification.

The above embodiments only express several implementations of the present disclosure, and the descriptions are relatively specific and detailed, but they shall not be construed as limiting the scope of the patent application. It should be noted that for those of ordinary skill in the art, several modifications and improvements can be made without departing from the concept of the present disclosure, and these all fall within the protection scope of the present disclosure.

What is claimed is:

1. A memory device, comprising:
a substrate;
a source line, disposed on the substrate and connected to the substrate;
a plurality of select lines, disposed on a side of the source line away from the substrate, wherein the plurality of select lines are disposed at intervals along a first direction perpendicular to the substrate;
a channel structure, extending through the plurality of select lines and being disposed along the first direction, wherein a bottom of the channel structure is connected to the source line, the channel structure comprises a gate dielectric layer, a charge trapping layer, a tunneling layer, a channel layer, and a core pillar, which are arranged in sequence along a direction from the plurality of select lines towards a center of the channel structure, and the core pillar comprises a first isolation layer, a conductive layer, and a second isolation layer, which are arranged in sequence along a direction away from the source line; and
a bit line, disposed on a side of the channel structure away from the source line.

2. The memory device according to claim 1, wherein the plurality of select lines comprises a source select line, a plurality of word lines, and a drain select line, which are arranged in sequence along the first direction.

3. The memory device according to claim 2, wherein a top surface of the first isolation layer is lower than the plurality of word lines, a bottom surface of the second isolation layer is higher than the plurality of word lines, and the conductive layer is disposed between the top surface of the first isolation layer and the bottom surface of the second isolation layer.

4. The memory device according to claim 1, wherein the memory device is a plurality of memory devices, and respective source lines of the plurality of memory devices are connected to a plurality of channel structures in a one-to-one correspondence; or
a group of the channel structures that are adjacently arranged are connected to the same source line.

5. The memory device according to claim 1, wherein a material of the channel layer comprises semiconductor or metal oxide.

6. The memory device according to claim 1, wherein a material of the gate dielectric layer comprises at least one of silicon oxide, silicon nitride, and silicon oxynitride; a material of the charge trapping layer comprises silicon nitride; and a material of the tunneling layer comprises silicon oxide or silicon oxynitride.

7. The memory device according to claim 2, wherein a portion of the source select line where intersects the channel structure constitutes a lower select transistor, the source select line covers a channel of the lower select transistor and is connected to a control gate of the lower select transistor, a portion of the drain select line where intersects the channel structure constitutes an upper select transistor, and the drain select line covers a channel of the upper select transistor and is connected to a control gate of the upper select transistor.

8. The memory device according to claim 3, wherein the first isolation layer is disposed between the conductive layer and the source line, and the second isolation layer is disposed between the conductive layer and the bit line.

9. The memory device according to claim 7, wherein the first isolation layer is located on an inner side of a channel layer of the lower select transistor, and the second isolation layer is located on an inner side of a channel layer of the upper select transistor.

10. The memory device according to claim 1, wherein the first isolation layer comprises a single-layer structure or a multi-layer structure, and the second isolation layer comprises a single-layer structure or a multi-layer structure.

11. The memory device according to claim 1, wherein a material of the conductive layer comprises at least one of zinc oxide, vanadium oxide, doped polysilicon, and conductive metal.

12. A memory device, comprising:
a substrate;
at least one source line, disposed on the substrate and connected to the substrate;
at least one memory string, disposed on a side of the at least one source line away from the substrate and connected to the substrate through the at least one source line, wherein the at least one memory string comprises a lower select transistor, a plurality of memory cells, and an upper select transistor, which are arranged in sequence along a first direction perpendicular to the substrate, and each of the plurality of memory cells comprises a memory transistor and a bypass resistor connected in parallel with the memory transistor;
a plurality of word lines, arranged at intervals along the first direction, wherein each of the plurality of word lines is connected to a control gate of the memory transistor arranged on the same layer;
a source select line, disposed below the plurality of word lines, and connected to a control gate of the lower select transistor;
a drain select line, disposed above the plurality of word lines, and connected to a control gate of the upper select transistor; and
at least one bit line, disposed on a side of the upper select transistor away from the substrate, and connected to the upper select transistor of the at least one memory string.

13. The memory device according to claim 12, wherein the at least one memory string comprises a plurality of memory strings and the at least one source line comprises a plurality of source lines, the plurality of source lines are connected to the plurality of memory strings in a one-to-one correspondence, or
a group of the memory strings that are adjacently arranged are connected to the same source line.

14. The memory device according to claim 13, wherein the at least one bit line comprises a plurality of bit lines, the plurality of memory strings are arranged in a plurality of columns along a second direction parallel to the substrate, the plurality of columns of memory strings are arranged at intervals along a third direction, and the third direction is parallel to the substrate and intersects the second direction; and
the plurality of bit lines are connected to each of the columns of memory strings, wherein the plurality of bit lines are along the second direction.

15. The memory device according to claim 12, wherein a resistance of the bypass resistor is greater than a channel equivalent resistance of the memory transistor when turned on and is less than a channel equivalent resistance of the memory transistor when turned off.

16. The memory device according to claim 12, wherein a portion of the word line where intersects the channel structure constitutes the memory transistor, the word line surrounds a channel layer of the memory transistor and is connected to a control gate of the memory transistor.

17. The memory device according to claim 12, wherein a storage state of the memory string is configured to be determined based on an accumulated voltage of the plurality of memory cells of the at least one memory string.

18. A manufacturing method for a memory device, comprising:
providing a substrate with a source line formed on a side of the substrate;
forming a stacked structure on a side of the source line away from the substrate, wherein the stacked structure comprises insulating layers and sacrificial layers, which are alternatively arranged;
forming a first hole which penetrates the stacked structure along a first direction perpendicular to the substrate and exposes a part of a top surface of the source line;
forming a channel structure in the first hole, wherein the channel structure comprises a gate dielectric layer, a charge trapping layer, a tunneling layer, a channel layer, and a core pillar, which are arranged in sequence along a direction from the stacked structure towards a center of the channel structure, and the core pillar comprises a first isolation layer, a conductive layer, and a second isolation layer, which are arranged in sequence along a direction away from the source line;
removing the sacrificial layers, and filling a conductive material in regions where the sacrificial layers are removed to form a plurality of select lines arranged at intervals along the first direction; and
forming a bit line on a side of the channel structure away from the source line.

19. The manufacturing method for the memory device according to claim 18, wherein forming the channel structure in the first hole comprises:
forming a gate dielectric layer, a charge trapping layer, a tunneling layer, and a channel layer, which cover an inner sidewall of the first hole in sequence, wherein at least a part of a bottom surface of the channel layer is in contact with the source line; and
forming a first isolation layer, a conductive layer, and a second isolation layer on an inner side of the channel layer, wherein the first isolation layer, the conductive layer, and the second isolation layer are arranged in sequence along a direction away from the substrate.

20. The manufacturing method for the memory device according to claim 18, wherein the manufacturing method comprises:
forming a plurality of source lines and a plurality of channel structures, wherein the plurality of source lines are connected to the plurality of channel structures in a one-to-one correspondence, and the first holes are formed on the plurality of source lines, respectively; or
forming a plurality of first holes on each of the plurality of source lines, and a group of the channel structures that are adjacently arranged are connected to the same source line.
